(19) United States
(12) Patent Application Publication
(10) Pub. No.: US 2011/0266587 A1
(43) Pub. Date: Nov. 3, 2011

(54) SEMICONDUCTOR DEVICE AND PRODUCTION METHOD THEREOF

(75) Inventors: Toshimichi Naruse, Gunma-ken (JP); Hideo Takada, Oota-shi (JP)

(73) Assignee: SANYO ELECTRIC CO., LTD., Moriguchi-city (JP)

(21) Appl. No.: 13/038,079

(22) Filed: Mar. 1, 2011

(30) Foreign Application Priority Data
Mar. 1, 2010 (JP) 2010-44457
Feb. 2, 2011 (JP) 2011-20458

(51) Int. Cl. H01L 33/52; H01L 31/18; H01L 31/0203

(52) U.S. Cl. 257/99; 257/433; 438/26; 438/64; 257/E33.058; 257/E31.117

(57) ABSTRACT

In some embodiments, a semiconductor device includes a semiconductor chip configured to receive or emit light, a chip mounting region for mounting the semiconductor chip, an electrode arranged surrounding the chip mounting region, an electric connecting element which electrically connects the semiconductor chip and the electrode, an optically-transparent element arranged on a top surface of the semiconductor chip and made of optically-transparent material, a protection film arranged on a top surface of the optically-transparent element so as to surround a light passing region through which the light passes, and a filler-contained insulating resin which seals the semiconductor chip, the electric connecting element, the electrode, the optically-transparent element, and the protection film in a state in which a top surface of the protection film and the light passing region surrounded by the protection film are exposed outside.

This application claims priority under 35 U.S.C. §119 to Japanese Patent Application No. 2010-44457 filed on Mar. 1, 2010 and Japanese Patent Application No. 2011-20458 filed on Feb. 2, 2011, the entire disclosure of each of which is incorporated herein by reference in its entirety.

### BACKGROUND OF THE INVENTION

1. Field of the Invention

Some preferred embodiments of the present invention relate, inter alia, to a semiconductor device which emits light or detects incoming light, and a production method thereof.

2. Description of the Related Art

The following description sets forth the inventor's knowledge of related art and problems therein and should not be construed as an admission of knowledge in the prior art.

A semiconductor device which emits light or detects incoming light is employed in various recent electric devices, such as, e.g., digital versatile discs (DVDs), or imaging devices using blue-rays.

For example, a light emitting device is represented by a semiconductor laser, and a light detecting device is represented by a light-receiving optical package. In an optical pickup module used in a DVD device, the light emitted from a built-in semiconductor laser is irradiated onto an optical disk via an objective lens, and the light reflected from the optical disk is introduced into a light-receiving package embedded in the module via a prism. This light-receiving optical package is normally of a hollow structure.

In such a light-receiving optical package, side walls are arranged on a printed-circuit board in a lattice-shaped manner, and a photonic device is mounted in each space defined by and surrounded by the four side walls. An upper opening of the space defined by the four side walls is covered with, for example, a glass plate. This technology is detailed by, for example, JP-2001-053180A (corresponding to U.S. Pat. No. 6,521,482 issued on Feb. 18, 2003).

A semiconductor package is normally sealed with resin molded by a transfer molding method. In view of a long developing history, fillers are added to sealing resin in order to accord the coefficient of thermal expansion of the sealing resin with the coefficient al of thermal expansion of Si which is a material of a semiconductor chip. In an optical package according to the present invention, however, the fillers cause scattering of light, and therefore fillers-contained sealing resin cannot be employed in the present invention. If no filler is added, the difference of coefficient of thermal expansion between the semiconductor material and the sealing resin becomes large, resulting in large stress applied to the semiconductor chip embedded in the sealing resin.

Furthermore, adding fillers deteriorates the viscosity of the sealing resin in a molten state, allowing flow of the molten resin through the mating face of the molding die, which in turn causes burrs. For such circumstances, in most cases, a hollow package sealed with a glass plate is employed.

Despite this, a transfer molding method using sealing resin with no filler has been achieved. In this method, photonic devices are mounted on a printed-circuit board and sealed with resin using a molding die at a time, and then subjected to dicing or die cutting.

In a hollow package 50 shown in FIG. 9, during the production step, a tip mounting tool and/or a bonding tool is required to be inserted in between the side wall 51 and the photonic device 52, which inevitably necessitates a margin therebetween. This prevents downsizing of the device, and also makes it difficult to attain the cost down due to the complexity of the step of adhering a glass plate.

On the other hand, in an optical semiconductor device 60 shown in FIG. 10, the thermoset resin 61 containing no filler was molded by a transfer molding method. In this case, however, burrs were generated due to the low viscosity of the thermoset resin 61, which presented a problem. Furthermore, the coefficient of thermal expansion (linear expansion coefficient) of the sealing resin and that of the substrate were different greatly. This caused warpage of the package, resulting in malfunction of the semiconductor chip. In addition, recent employment of light having a wave length of 405 nm in blue-ray discs BD presents a problem of light resistance of resin. The light is close to ultraviolet light, causing decoloration of the resin.

Under the circumstances, as disclosed by JP-2006-19363-A, a technology in which molding is performed with a die-shaped glass plate disposed on a chip has been proposed. In this proposal, the glass plate is brought into contact with an inner surface of a molding die, which presents a problem that the molding die causes scratches or damages of the surface of the glass plate. In order to prevent generation of possible scratches or damages, a flexible resin sheet was conventionally adhered to the entire inner surface of the upper die constituting the molding die at the time of the molding. However, the peeling operation of the resin sheet after the molding causes accumulation of static electrical charges in the glass plate, which in turn becomes an issue that the electrically charged glass plate absorbs dusts or the like.

Furthermore, in cases where a resin sheet is attached to the die, the resin sheet production device and the resin sheet cause high production costs. Moreover, when the glass plate is brought into contact with the resin sheet, the glass plate is bit into the resin sheet, causing a problem that certain portions of the glass plate slightly protrude from the package in the finished state. If the projected corner of the glass plate is hit by something, the corner may be chipped.

The produced semiconductor device is delivered to an assembly line for the subsequent mounting step. The delivery step may cause adherence of dusts on the semiconductor device and/or damage of the semiconductor device. Further, the production step should require careful handling.

On the other hand, JP-2004-319530-A discloses a method of molding a chip while covering a protection film on a glass plate. This method requires removal of the protection film after the molding step, which requires a troublesome removal work. Furthermore, at the time of removing the protection film, a charging step is required, which in turn causes adhesion of dusts on the glass surface.

The description herein of advantages and disadvantages of various features, embodiments, methods, and apparatus disclosed in other publications is in no way intended to limit the present invention. For example, certain features of the preferred embodiments of the invention may be capable of overcoming certain disadvantages and/or providing certain advantages, such as, e.g., disadvantages and/or advantages discussed herein, while retaining some or all of the features, embodiments, methods, and apparatus disclosed therein.

### SUMMARY OF THE INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide a semiconductor device sealed with filler-contained insulating resin capable of preventing occurrence of warpage of the device.

Among other potential advantages, some embodiments can provide a semiconductor device capable of preventing damages and/or contamination of a light passing region.

Among other potential advantages, some embodiments can provide a semiconductor device high in reliability.

Among other potential advantages, some embodiments can provide method of producing a semiconductor device capable of preventing warpage of the device.

According to a first aspect of the present invention, among other potential advantages, some embodiments can provide a semiconductor device including:

a semiconductor chip configured to receive or emit light;

a chip mounting region for mounting the semiconductor chip;

an electrode arranged around the chip mounting region;

an electric connecting element which electrically connects the semiconductor chip and the electrode;

an optically-transparent element arranged on a top surface of the semiconductor chip and made of optically-transparent material;

a protection film arranged on a top surface of the optically-transparent element so as to surround a light passing region through which the light passes; and

a filler-contained insulating resin which seals the semiconductor chip, the electric connecting element, the electrode, the optically-transparent element, and the protection film in a state in which a top surface of the protection film and the light passing region surrounded by the protection film are exposed outside.

In some examples, it can be configured such that the semiconductor device further includes a supporting board on which the chip mounting island and the electrode are arranged.

According to a second aspect of the present invention, some preferred embodiments provide a method of producing a semiconductor device, comprising the steps of:

preparing a plurality of semiconductor units each including a semiconductor chip configured to receive or emit light, a chip mounting region for mounting the semiconductor chip, an electrode arranged around the chip mounting region, an electric connecting element which electrically connects the semiconductor chip and the electrode, an optically-transparent element arranged on a top surface of the semiconductor chip and made of optically-transparent material, and a protection film arranged on a top surface of the optically-transparent element so as to surround a light passing region through which the light passes;

arranging the plurality of semiconductor units in a molding die in a matrix manner;

filling a filler-contained resin in the molding die so that the plurality of semiconductor units are sealed with the filler-contained resin in a state in which a top surface of the protection film and the light passing region surrounded by the protection film of each of the plurality of the semiconductor units are exposed outside;

removing the plurality of semiconductor units from the molding die; and

dicing the plurality of semiconductor units to obtain a plurality of detached semiconductors.

According to the aforementioned semiconductor device and the production method, the semiconductor chip can be sealed with a filler-contained insulating resin. This enables adjustment of the coefficient of thermal expansion of the insulating resin, which in turn enables prevention of possible warpage of the device due to the difference between the coefficient of thermal expansion of the insulating resin and that of the material of the semiconductor chip.

By providing the protection film on the surface of the optically-transparent element, the protection film prevents the optically-transparent element from being contacted by something. Furthermore, the protection film surrounding the light passing region can prevents invasion of the insulating resin into the light passing region.

Since an optically-transparent element made of, e.g., glass, which does not contain fillers is used and sealed by a filler-contained insulating resin, the viscosity of the insulating resin to be injected in a molding die can be increased, which prevents possible generation of burrs to be created at the mating face of the molding die.

In a produced semiconductor device, the surface of the package and the surface of the protection film become substantially flush with each other, resulting in a smooth surface. The opening portion of the protection film can be reduced, which prevents possible damages of the optically-transparent element and possible contamination of the optically-transparent element due to abrasion of the protection film.

In cases where the protection film is made of polymerized resin, possible generation of dusts due to abrasion of the protection film can be reduced.

Furthermore, the protection film enables easy handling of the semiconductor device during the assembling step because of the existence of the protection film.

The protection film shuts off stray lights, preventing malfunction of the device.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by way of example, and not limitation, in the accompanying figures, in which:

FIG. 1A is a schematic side cross-sectional view showing a semiconductor according to a first embodiment of the present invention;

FIG. 1B(1) is an explanatory perspective view showing an optically-transparent element and a protection film of the semiconductor shown in FIG. 1A;

FIG. 1B(2) is a perspective view showing a modified embodiment in which a protection film is formed into a ring-shape;

FIG. 1C is a schematic side cross-sectional view showing a semiconductor according to a modified embodiment;

FIG. 1D is a schematic view showing the semiconductor shown in FIG. 1;

FIG. 2A is a schematic side cross-sectional view showing a semiconductor according to a second embodiment of the present invention;

FIG. 2B is a perspective view showing a modified embodiment;

FIG. 2C is a transparent top view of the semiconductor device shown in FIG. 2A;

FIG. 2D is a top view of a modified embodiment;

FIG. 2E is a bottom view of another modified embodiment:

FIG. 3A is an explanatory view of a production method of the present invention;

FIG. 3B is a perspective view showing a cut unit;

FIG. 3C is a perspective view of a modified embodiment of the cut unit;

FIG. 3D is a perspective view of another modified embodiment of the cut unit;

FIG. 3E is s a perspective view of still another modified embodiment of the cut unit;

FIGS. 4A and 4B are explanatory views showing production steps of a production method of the present invention;

FIGS. 5A and 5B are explanatory views showing subsequent steps of the production method of the present invention;

FIGS. 6A(1), 6A(2), 6B(1) and 6B(2) are explanatory views showing steps of another production method of the present invention;

FIG. 7 is a cross-sectional view showing a molding step of the production method;

FIG. 8 is a cross-sectional view of a semiconductor device obtained by the method;

FIG. 9 is a perspective view showing a conventional semiconductor device;

FIG. 10 is a cross-sectional view of another conventional semiconductor device;

FIGS. 11A and 11B are explanatory views showing a lead frame according to the present invention;

FIG. 12 is a perspective view showing an optical pickup module employing a semiconductor device of the present invention; and

FIGS. 13 A and 13B are cross-sectional views each showing a semiconductor device employing a Si interposer according to the present invention.

### DETAILED DESCRIPTION OF THE PREFERRED EMBODIMENTS

In the following paragraphs, some preferred embodiments of the present invention will be described by way of example and not limitation. It should be understood based on this disclosure that various other modifications can be made by those in the art based on these illustrated embodiments.

### FEATURE OF THE PRESENT INVENTION

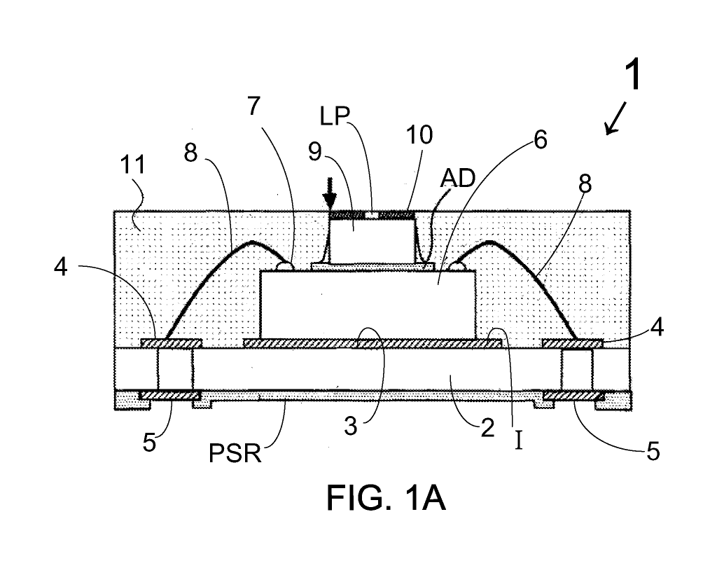

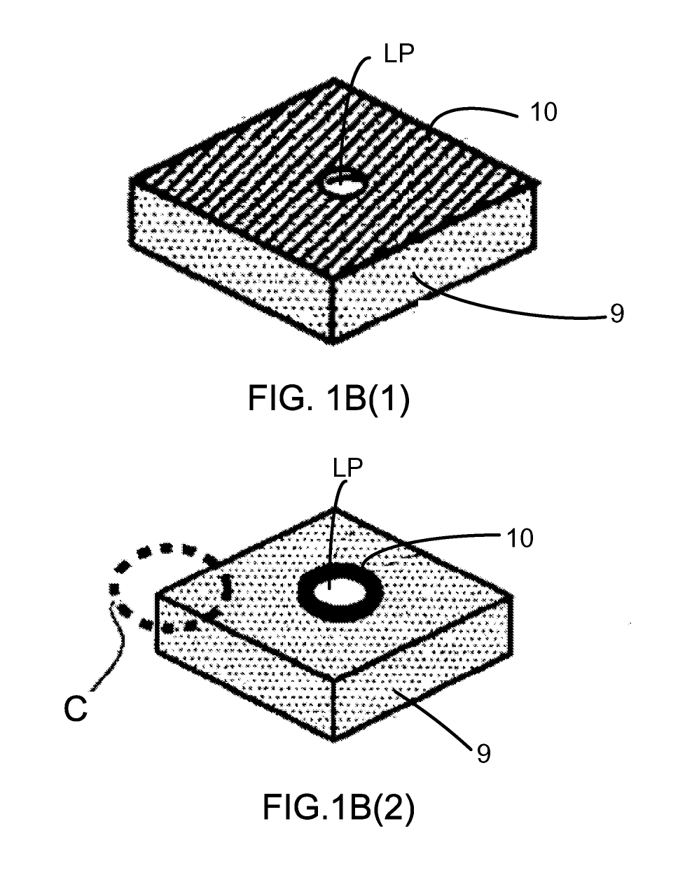

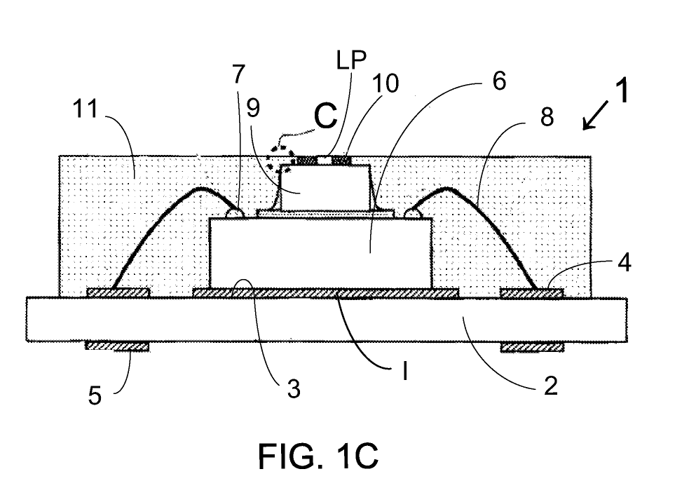

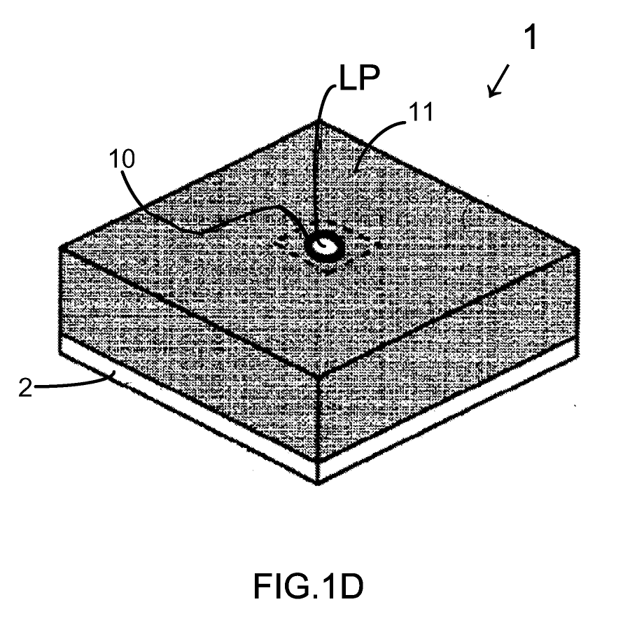

The present invention will be explained with reference to en embodiment shown in FIG. 1. A semiconductor device shown in FIG. 1 includes a semiconductor chip 6 configured to receive and/or emit light, a chip mounting region 3 for mounting the semiconductor chip 6, lead frames (electrodes) 4 arranged around the semiconductor chip 6, lead wires (electric connecting element) 8 which electrically connect the semiconductor chip 6 (electrode 7 formed on the chip 6) and the lead frames 4, an optically-transparent element 9 arranged on a top surface of the semiconductor chip 6 and made of an optically-transparent material, a protection film 10 arranged on a top surface of the optically-transparent element 9 so as to surround a light passing region LP through which the light passes, and a filler-contained insulating resin 11 which seals the semiconductor chip 6, the lead wires 8, the lead frames 4, the optically-transparent element 9, and the protection film 10.

In semiconductor devices not configured to receive and/or emit light, filler-contained insulating resin is generally employed as the insulating resin. Such filler can be, e.g., oxide silicon, alumina, or glass fibers. The mixing rate of the filler is decided considering the coefficient of thermal expansion of the semiconductor chip, the supporting board, or the lead frames and the coefficient of thermal expansion of the insulating resin. However, mixtures such as fillers cause diffuse reflection of light. For this reason, it was considered that filler-contained insulating resin cannot be employed in a semiconductor package configured to receive and/or emit light. In detail, such fillers existed in a light passing region of the semiconductor package through which light passes cause diffusion reflection of light, which in turn prevents accurate signal communication.

In the meantime, epoxy series thermo-setting resin is generally used as such insulating resin. If such thermo-setting resin not containing fillers is employed as a sealing material, the resin flows out through the mating face of the upper and lower molding dies during the molding step due to the low viscosity, resulting in generation of burrs (see JP-2007-305859-A).

In the present invention, a glass plate or block member having a size larger than the size of the light passing region LP (laser light passage through which light to be received by or emitted from the semiconductor chip passes) is used as an optically-transparent element 9 and the remaining portion of the semiconductor chip is sealed with a filler-contained insulating resin. This eliminates the use of low viscosity insulating resin.

The employment of filler-contained insulating resin 11 eliminates inconsistency of the coefficient of thermal expansion between Si which is a material of the semiconductor chip 6 and the insulating resin to thereby prevent warpage of the semiconductor device 1.

Furthermore, providing the protection film 10 made of resin and arranged to surround the light passing region LP prevents the optically-transparent element 9 from being directly brought into contact with an inner surface of a molding die during the sealing step, which enables sealing of the semiconductor chip, etc., without causing damages of the optically-transparent element 9. In the sealing step, the protection film 10 prevents the filler-contained insulating resin from being introduced into the opening of the protection film 10 (i.e., the light passing region LP above the optically-transparent element 9).

One of the features of the present invention resides in that the optically-transparent element 9 is arranged on a top surface of the semiconductor chip 6 and that the protection film 10 is arranged on a top surface of the optically-transparent element 9 so that the protection film 10 comes into direct contact with the inner surface of the molding die. This in turn causes the inner surface of the molding die to be brought into direct contact with the protection film 10, which prevents possible damages of the optically-transparent element 9. As a result, a conventional resin sheet adhered to an inner surface of the molding die, which was explained in the section of “Description of the Related Art” of this document, can be eliminated. It should be noted, however, that the present invention does not exclude the use of such a conventional resin sheet although the employment of such a resin sheet causes high production costs.

Employing the optically-transparent element 9, such as, e.g., a glass plate or a glass block member, and the protection film 10, and sealing the periphery thereof with a filler-contained insulating resin prevent occurrence of burrs at the mating face of the molding die.

In the finished semiconductor device 1, the insulating resin 11 becomes integral with the side periphery of the protection film 10, and the surface of the insulating resin 11 and the surface of the protection film 10 become substantially flush with each other. Thus, the upper surface of the portion of the optically-transparent element 9 corresponding to the light passing region LP is positioned lower than the remaining upper surface of the semiconductor device 1. This structural features prevent possible damages of the optically-transparent element 9, and also prevent abrasion of the protection film 10, resulting in a reduced amount of dusts which could be generated from the protection film 10 due to the abrasion. In the embodiment shown in FIG. 1B(1), only the portion of the protection film 10 corresponding to the light passing region LP is etched, and the remaining portion thereof is arranged on the top surface of the optically-transparent element 9. In the alternative embodiment shown in FIG. 1B(2), the protection film 10 is etched into a ring-shape surrounding the light passing region LP. In this alternative embodiment shown in FIG. 1B(2), the top surface of the optically-transparent element 9 located outside the protection film 10 is thinly covered with a resin material during the molding step. In FIG. 1B(2), the portion C surrounded by the dotted line is thinly covered with a resin material, and the thickness of the covered resin material is approximately the same as the thickness of the protection film 10. The thin resin material is integrally formed with the remaining resin 11, which prevents detachment of the optically-transparent element 9. Furthermore, as shown in FIG. 1A, the boundary face between the optically-transparent element 9 and the resin material 11 is not exposed at the top surface of the semiconductor package 1, which can expect improved moisture resistance performance.

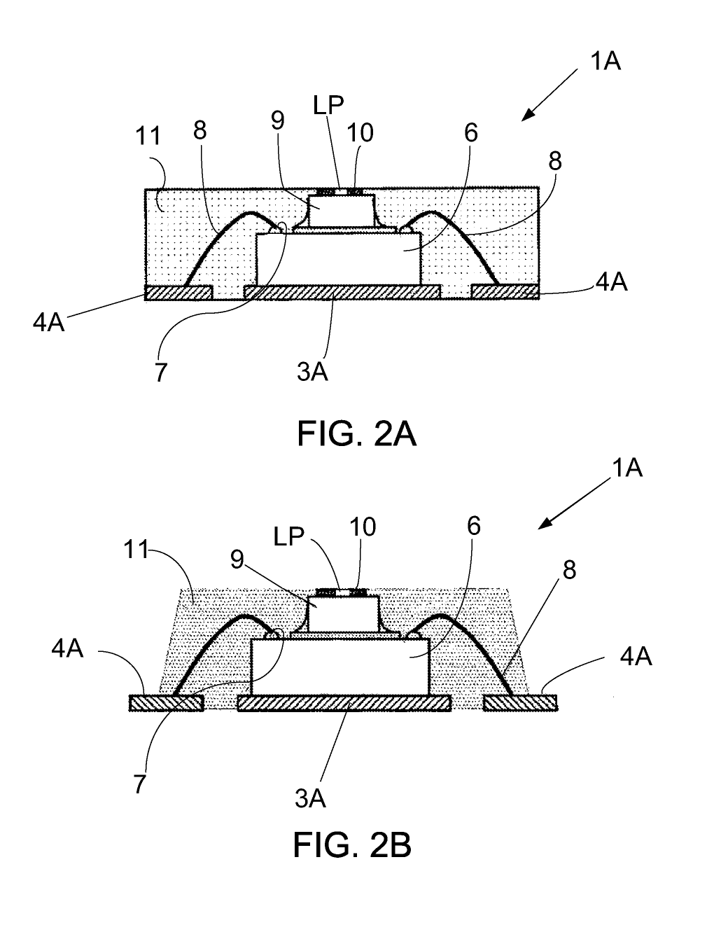

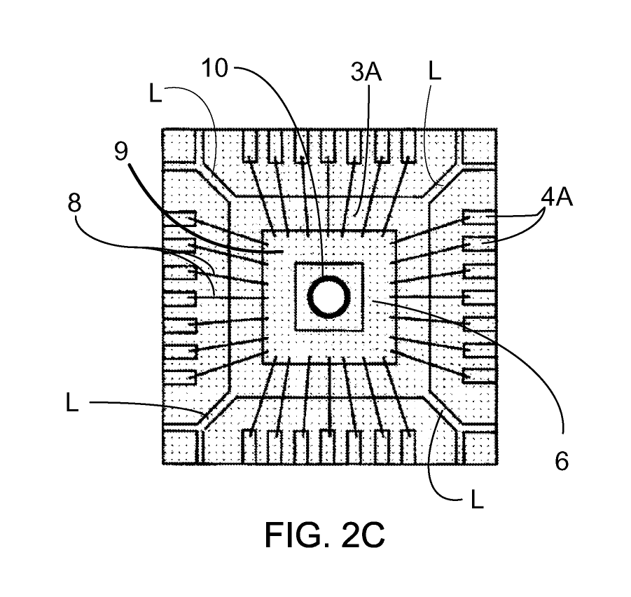

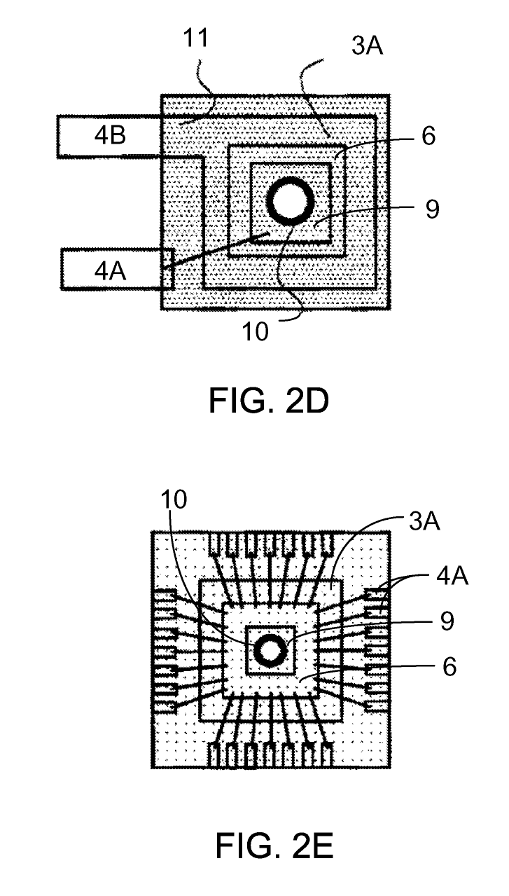

In the present invention, it is preferable that the optically-transparent element 9 is transparent with respect to light and has a certain thickness. In the embodiments shown in FIGS. 1 and 2, the optically-transparent element 9 preferably has a thickness so that the top surface of the optically-transparent element 9 is positioned higher than the upper most portion of the electric connecting element (lead wire) 8. The material of the optically-transparent element 9 can be, for example, glass, or transparent resin. On the other hand, the protection film 10 can be, for example, a thinly applied resin member, a film-like or sheet-like resin member, or a thin plate-like resin member. As shown in FIG. 1B, it is preferable that the protection film 10 is a member capable of being etched to form, for example, the light passing region LP. For example, liquid resin, such as, e.g., solder resist, can be preferably used as the protection film 10 due to the easy coating property and easy etching property.

In general, photo solder is used without being subjected to a polymerization step such as a heat treatment. However, during the production steps including an assembling step, if the photo solder is brought into contact with something, there is a possibility that dusts, debris or the like will be generated and remain in the light passing region LP.

To solve the drawbacks, in the present invention, it is preferable to polymerize a resin. In a preferable embodiment, an imide resin is thinly applied on a large glass plate, patterned, and then polymerized by applying heat to obtain a polyimide resin. As a result, the bonding force of the imide resin increases, which in turn can prevent possible generation of dusts, debris or the like. Such polyimide resin is softer than photo resistor or the insulating resin, which can reduce the force to be applied to the optically-transparent element 9 and restrain deterioration of the optically-transparent element 9.

Furthermore, the opening portion (light passing region) LP of the protection film 10 is preferably limited to a small area as shown in, for example, FIG. 1D, which prevents or effectively controls entering of dusts, debris or the like in the opening portion (light passing region) LP.

On the other hand, the protection film 10 enables relatively easy assembling operations as compared to the assembling operations of a conventional semiconductor device as explained in the Related Art. In addition, there is a low possibility that the optically-transparent element 9 positioned below the protection film 10 comes into contact with something.

Furthermore, by arranging the optically-transparent element 9 on the top surface of the semiconductor chip 6, especially in the region for receiving and/or emitting light, the remaining surface of the semiconductor chip 6 can be sealed with an insulating resin.

Thus, the coefficient of thermal expansion of the insulating resin 11 can be approximated to the coefficient of thermal expansion a of Si which is a material of the semiconductor chip 6. In cases where the supporting board (substrate) 2 contains fillers, such as, e.g., glass fibers or glass fillers, the coefficient of thermal expansion of the supporting board 2 can also be adjusted to effectively prevent warpage of the entire device.

The present invention can be applied to a method using a molding die. For example, the present invention can be applied to all packages capable of being sealed by a transfer molding method. Especially, in considering miniaturization, the present invention can be effectively applied to a production method called a MAP method which employs a supporting board and a lead frame.

### FIRST EMBODIMENT

FIG. 1 shows a semiconductor device 1 according to a first embodiment of the present invention. This semiconductor device 1 employs a supporting board (substrate) 2. The supporting board 2 is a member in which at least surfaces thereof have insulation properties. Concretely, the supporting board 2 can be, for example, a ceramic board, a resin board, or a surface-insulated metal board. Preferred resin boards can be exemplified by an insulation board comprised of a core made of an insulating resin and Cu patterns formed on both surfaces of the core, and an insulation board comprised of a core made of Cu, insulating resin layers formed on both surfaces of the core, and Cu patterns formed on the insulating resin layer, which are called “interposer.” The insulating resin can be, for example, epoxy series resin or polyimide series resin, and contains fillers, such as, e.g., glass fibers, or particles of silicon oxide (silica), alumina or glass. In this embodiment, a glass epoxy resin board is employed as the supporting board 2.

The top surface of the supporting board 2 has a chip mounting region 3 for mounting the semiconductor chip 6, and is provided with internal electrodes 4 electrically connected to the semiconductor chip 6 (more specifically, a pad 7 formed on the semiconductor chip 6) and arranged therearound. On the rear surface of the supporting board 2, outer electrodes 5 electrically connected to the corresponding inner (internal) electrodes 4 are provided. This electrical connection between the inner electrode 4 and the outer electrode 5 is performed by an electrical material provided in a through-hole extending from the top surface of the supporting board 2 to the rear surface thereof. Depending on the necessity, photo solder resist PSR is provided on the rear surface of the supporting board 2 except for the surface of the outer electrode 5, and the exposed outer electrode 5 is covered by a soldering material.

In this embodiment, for convenience of easy illustration and easy explanation, two-layer wiring structure is illustrated, but the present invention allows multilayer wiring structure having more than three-layers or a single layer wiring structure. In the case of a single layer wiring structure, the supporting board 2 has a through-hole at a location corresponding the inner electrode 4 and the rear surface of the electrode 4 exposed to the through-hole is covered with a soldering material.

On the chip mounting region 3 of the supporting board 2, a semiconductor chip mounting island I, which is made of the same material of the internal electrode 4 and the outer electrode 5 and contains Cu as a main ingredient, is arranged. The semiconductor chip 6 is arranged on the island I and the rear surface of the semiconductor chip 6 is adhered to the top surface of this island I. As the island I, in general, a Ni-plated or Au-plated member can be preferably used, and the semiconductor chip 6 is adhered to the Ni-plated or Au-plated member via a soldering material, Ag paste, or insulating adhesive. In the case of fixing the semiconductor chip 6 to the chip mounting region 3 using insulating adhesive, the island I can be omitted so that semiconductor chip 6 is directly fixed to the supporting board 2. Furthermore, in cases where the semiconductor chip 6 is a high-speed processing chip and generates a large amount of heat, it can be configured such that the through-hole is formed as a thermal via (i.e., thermal via hole) and the outer electrode is provided at the rear side of the supporting board 2.

The semiconductor chip 6 is configured to emit light or receive incoming light. For example, the former, i.e., a light emitting semiconductor chip, can be exemplified by an LED or a laser, and the latter, i.e., a light receiving semiconductor chip, can be exemplified by a photodiode, or a photodiode built-in optical IC. The photodiode or the optical IC can be used as a part of a set called “DVD” or “Blue-ray.” These are used as an optical pickup configured to detect laser light reflected by an optical disk to detect “1” and “0” signals or detect the spot position. The semiconductor chip 6 is provided with electrodes 7 as pads arranged at the peripheral portion of the chip and a diffusion region in chip (photodiode element) having an optical processing function and formed by the semiconductor production process.

In cases where the rear surface of the semiconductor chip 6 is grounded, rear electrodes (not shown) are provided on the rear surface of the semiconductor chip 6 and electrically connected to the island I with soldering material or Ag paste. The electrode (pad) 7 of the semiconductor chip 6 and the inner electrode 4 are electrically connected with a metal thin wire 8. In cases where the rear surface of the semiconductor chip 6 is not grounded, the semiconductor chip 6 can be connected to the supporting board 2 via insulating adhesive.

On the top surface of the semiconductor chip 6, the optically-transparent element 9 is arranged. This element 9 is made of an optically-transparent material, such as, e.g., glass or optically-transparent resin (in general, plastic material is preferably used). The optically-transparent material is cut into a die shape and the protection film 10 is formed on the cut piece so as to surround an optical passing region LP which is a passage through which light passes. For example, in the case of a laser chip, the optical passing region LP is a passage through which the emitted light goes out, and a glass plate/block as an optically-transparent element is arranged in the passage and the protection film 10 is provided on the top surface of the glass plate/block so as to surround the passage.

In the case of an optical IC employed in a pickup, it is configured such that incoming light (e.g., laser light) from an outside is irradiated to a photodiode formed in an IC. Such laser light is irradiated on a surface of a glass plate/block as an optically-transparent element in a spot-like manner, and a region having a size (e.g., 0.7 mm in diameter) larger than the spot diameter of the laser light on the surface of the glass plate/block is surrounded by the protection film.

FIGS. 1B(1) and 1B(2) each show an example of the optically-transparent element 9 which is a dice-shaped glass plate having a top surface, a rear surface, and four side surfaces. In these examples, the shape is rectangular as seen from the top, but can be any shape. For example, the shape as seen from the top can be round or polygonal. The square shaped optically-transparent element 9 can be easily produced by dicing processing which will be explained later. Shapes other than a square shape can be produced by, for example, punching processing or etching processing. The rear surface of the optically-transparent element 9 is adhered to the top surface of the semiconductor chip 6 via an adhesive layer AD, and the top surface thereof is covered with the protection film 10. On the rear surface of the protection film 10, an antireflection film (not shown) can be provided.

The optically-transparent element 9 is arranged on the semiconductor chip 6 and sealed with an insulating resin 11. In a molding step, in a state in which the protection film 10 is in contact with the inner surface of the molding die which forms a cavity, the insulating resin 11 seals the top surface of the supporting board 2 and the semiconductor chip 6, and is in a close-contact with the side surfaces of the optically-transparent element 9 and the outer side surfaces of the protection film 10 to seal them.

In this embodiment, since a glass plate/block is employed as the optically-transparent element 9, without employing a low-viscosity resin, the filler-contained resin 11 can be employed to surround the optically-transparent element 9. The filler can be, for example, particles of silicon oxide (silica), alumina or glass, or glass fibers.

Although the size of the optically-transparent element 9 differs depending on the size of the package and that of the semiconductor chip 6, if the package is 4 mm in width×5 mm in length×0.85 mm in thickness and the semiconductor chip 6 is 2.12 mm in width×2.5 mm in length, 0.33 mm in thickness, the size of the optically-transparent element 9 can be, for example, 1.1 mm in width, 1.1 mm in length, and 0.25 mm in thickness, which occupies 1.7% of the entire package. The volume amount of the insulating resin occupies 12% of the entire volume of the package.

The planer size of the optically-transparent element 9 merely occupies 6% of the planer size of the package 1.

Thus, by employing an insulating resin and adjusting the amount of filler in the insulating resin, inconsistency of the coefficient of thermal expansion among the supporting board 2, the insulating resin 11 and the semiconductor chip 6 can be adjusted, which in turn can prevent possible occurrence of warpage of the package.

As shown in FIGS. 1A and 1C, the surface of the protection film 10 and the surface of the insulating resin 11 are generally flush with each other. Possible external contacts do not cause damages of the optically-transparent element 9 made of, e.g., glass. An outwardly protruded protection film 10 becomes generation source of dusts, debris or the like, which may cause contamination of the light passing region LP. However, in this embodiment, since the surface of the protection film 10 and the surface of the insulating resin 11 are substantially flush with each other, the possible contamination of the light passing region LP can be reduced. For this reason, even in the assembling steps, strict management is not required, resulting in easy handling.

The optically-transparent element 9 formed into a dice-shaped piece can be held with a suction collet attached to a bonding device, which will be explained together with the production method later. Especially, in this embodiment, the surface of the protection film 10 and the surface of the insulating resin 11 are substantially flush with each other, which enables suction by the suction collet.

This embodiment shown in FIG. 1A is formed by a MAP (Matrix Array Packaging) method which will be explained later, and therefore the side surface of the supporting board 2 and that of the insulating resin 11 are substantially flush with each other. As shown in FIG. 1C, however, molding in individually can be performed so that the sealing portion 11 is smaller than the supporting board 2.

The characteristic shape can be seen from, for example, FIG. 1D. A thin rectangular solid package 1 sealed with a black-colored resin has, at its top surface, a small green-colored protection film 10 which merely occupies less than 10% of the top surface. The central portion of the protection film 10 is exposed outside and constitutes a light passing passage (region) LP. The package looks like a package having a small round eye on the top surface thereof.

Due to this structure, the package allows passing of incoming narrowed laser light, and can intercept disturbance light irradiated outside of the light passing region LP with the protection film 10, which can reduce optical noise.

Now, the difference between the embodiment shown in FIG. 1B(1) and the embodiment shown in FIG. 1B(2) will be explained. In the embodiment shown in FIG. 1B(1), a protection film 10 is formed on the entire region of the top surface of the optically-transparent element 9 except for the light passing region LP of 0.7 mm in diameter. On the other hand, in the embodiment shown in FIG. 1B(2), a protection film 10 is formed so as to surround the light passing region LP in a ring-shape. The inner diameter of the protection film 10 is about 0.7 mm, and the outer diameter thereof is about 0.9 mm. In the case of the structure shown FIG. 1B(1), it is practically sufficient to prevent possible invasion of moisture from the boundary face of the optically-transparent element 9 and the insulating resin 11 into the device and/or to prevent possible breakage at the boundary face. However, as shown by the arrow in FIG. 1A, the boundary face of the optically-transparent element 9 and the insulating resin 11 coincide with the boundary face of the protection film 10 and the insulating resin 11. This might cause possible invasion of moisture from the portion pointed by the arrow or might cause generation of possible cracks therefrom or breakage at the boundary under certain special conditions although the possibility is very low. On the other hand, in the case of the structure shown in FIG. 1B(2), as shown in FIG. 1D, the insulating resin 11 covers the peripheral portion of the top surface of the optically-transparent element 9 positioned outward of the ring-shaped protection film 10.

In this structure, the boundary face of the protection film 10 and the insulating resin 11 is positioned at the inner side of the top surface of the optically-transparent element 9, which more assuredly prevents occurrence of possible cracks/breakage and/or invasion of moisture. Furthermore, the insulating resin 11 covers the portion surrounded by the circle C shown by the dotted line in FIGS. 1B(2) and 1C, which prevents detachment of the optically-transparent element 9.

In cases where filler is contained in the portion surrounded by the circle C, it is necessary that the thickness of the protection film 10 is about 50 μm to 100 μm. In cases where no filler is contained in the portion surrounded by the circle C, it is enough that the thickness is 50 μm or less. In cases where resin such as polyimide resin capable of being polymerized with light such as UV is used, the resin can be polymerized as polyimide, which reduces generation of dusts, debris or the like due to possible contacts with a molding die.

### SECOND EMBODIMENT

FIG. 2 shows a semiconductor device 1A according to a second embodiment of the present invention. In this embodiment, electrodes (lead frames) 4A and an island 3A are embedded at the rear side of a resin package with the electrodes 4A and island 3A exposed. This structure can be formed by various methods. For example, this structure can be formed by molding in a state in which the rear sides of the electrodes 4A and the island 3A are in contact with a molding die. Alternatively, molding is performed using a copper plate having electrodes 4A and an island 3A formed by half-etching, and the rear side of the plate is removed after the molding. Alternatively, molding is performed using a board, electrodes 4A and an island 3A provided on the board, and then the board is removed after the molding. Such sealing can be performed by, for example, a MAP method and an individual molding method.

Now, a semiconductor device produced by a MAP method will be explained. In the following explanation, the same reference symbols as those used in FIG. 1 are allotted to the corresponding portions.

FIG. 2C is a transparent top view of the semiconductor device 1A shown in FIG. 2A. This device 1A includes a top surface, a rear surface, and four side surfaces. This device 1A includes a rectangular island 3A. This island 3A is provided with four hanging leads L extending outward from the corners of the island 3A. Each hanging lead L is branched in the longitudinal middle portion thereof.

Arranged around the island 3A are leads (electrodes) 4A with one end facing inward and the other end facing outward. The outward end of the lead 4A and the side surface of the package (semiconductor device) 1A are flush with each other. On the island 3A, in the same manner as in the first embodiment, a semiconductor chip 6 is mounted. Each of connecting electrodes (pad) 7 formed on the top surface of the semiconductor chip 6 is electrically connected to one end of corresponding lead 4A with a metal thin wire (electrical connecting element) 8. On the top surface of the semiconductor chip 6, an optically-transparent element 9 is mounted. This optically-transparent element 9 is the same in structure as that of the first embodiment, and has a protection film 10 thereon. In the embodiment shown in FIG. 2A and its modified embodiment shown in FIG. 2B, a ring-shaped protection film 10 is provided. In these embodiments, however, the protection film 10 can be formed on the entire surface of the optically-transparent element 9 as shown in FIG. 1A.

The elements of the semiconductor device including the optically-transparent element 9 are sealed with an insulating resin 11. In the molding step, in a state in which the protection film 10 is in contact with an inner surface of a molding die, molding is performed to thereby seal the island 3A, the leads 4A, the metal thin wires 8, and the semiconductor chip 6 with the insulating resin 11. The insulating resin 11 covers the side surfaces of the optically-transparent element 9 and the outer peripheral portion of the top surface of the optically-transparent element 9 located outward of the outer peripheral side of the protection film 10.

In the same manner as in the first embodiment, the optically-transparent element 9 is smaller than the entire package and optically transparent, which allows the use of filler-contained insulating resin 11. For example, the insulating resin 11 can preferably contain fillers, such as, e.g., glass fibers, or particles of silicon oxide (silica), alumina or glass. The optically-transparent element 9 has a size which covers a part (for example, from ½ to 1/10) of the semiconductor chip 6, and therefore the volume of the insulating resin 11 accounts more than half of the entire volume of this device 1A although it depends on the size. Accordingly, by adjusting the amount of the fillers, the coefficient of thermal expansion can be adjusted to prevent possible warpage of the package. Even if the entire package is warped, the insulating resin 11 covering the periphery of the top surface of the optically-transparent element 9 up to the peripheral edge of the protection film 10 prevents generation of gaps at the boundary between the insulating resin 11 and the optically-transparent element 9 and also prevents detachment of the optically-transparent element 9.

The semiconductor device 1A shown in FIG. 2A is produced by a MAP method employing lead frames, and therefore formed into a hexahedron having a top surface, a rear surface, and four side surfaces. This side surface of this device 1A coincides with the outer end face of the lead 4A.

FIG. 2B shows a modified embodiment which is an individually molded semiconductor device 1A. Considering easy detachment of the molding die, this device 1A is formed into a hexagonal structure with slightly inclined side surfaces. In detail, as shown in FIG. 2B, the side surfaces are inclined inwardly from the bottom of the package toward the top thereof. The outer end portion of the lead 4A is protruded from the side surface of the package.

FIG. 2D shows another modified embodiment which has a two-terminal structure. In this structure, the rear surface of the semiconductor chip, which is a diode, is electrically connected to the island 3A. One of the leads 4B is provided at the upper side in FIG. 2D. The electrode provided on the top surface of the semiconductor chip 6 is electrically connected to the other lead 4A located at the lower side in FIG. 2D apart form the island 3A via a metal thin wire. The island 3A and the semiconductor chip 6 are sealed with end portions of the leads 4A and 4B protruded outward of the package. Furthermore, in the same manner as in the second embodiment shown in FIG. 2A, an optically-transparent element 9 is mounted on the top surface of the semiconductor chip 6, and a protection film 10 is provided on the top surface of the optically-transparent element 9 so as to surround the light passing region LP. This is also individually molded, and the insulating resin is filled in a state in which the protection film 10 is in contact with the inner surface of the molding die.

The embodiment shown in FIG. 2D is realized by a method other than the aforementioned lead frame, and is of a structure that requires no supporting lead since the island and the leads are formed by half-etching a Cu foil or a pattern thereof is formed on a supporting substrate.

FIG. 2E shows a modified embodiment similar to the embodiment shown in FIG. 2C except that the island 3A has no hanging lead. The cumulative explanation will be omitted by allotting the same or corresponding reference numeral to the corresponding portion.

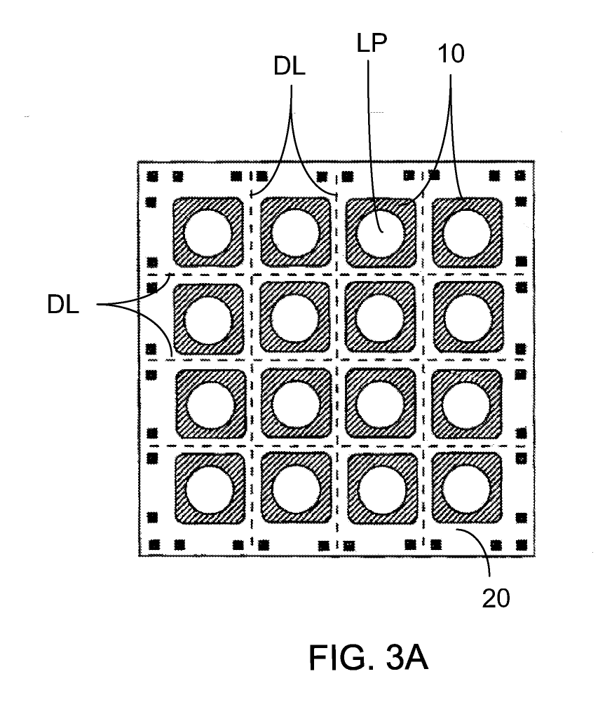

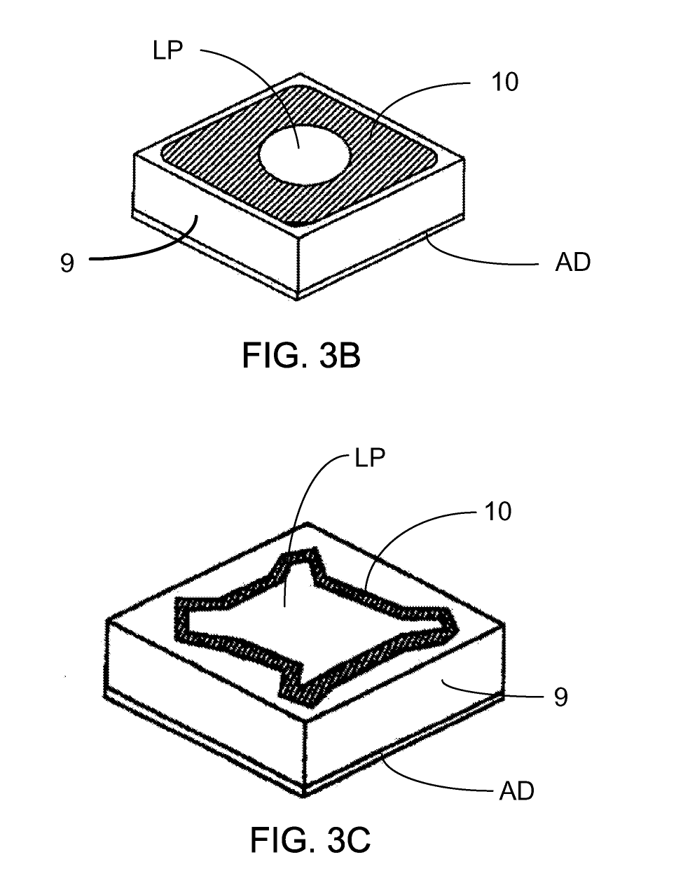

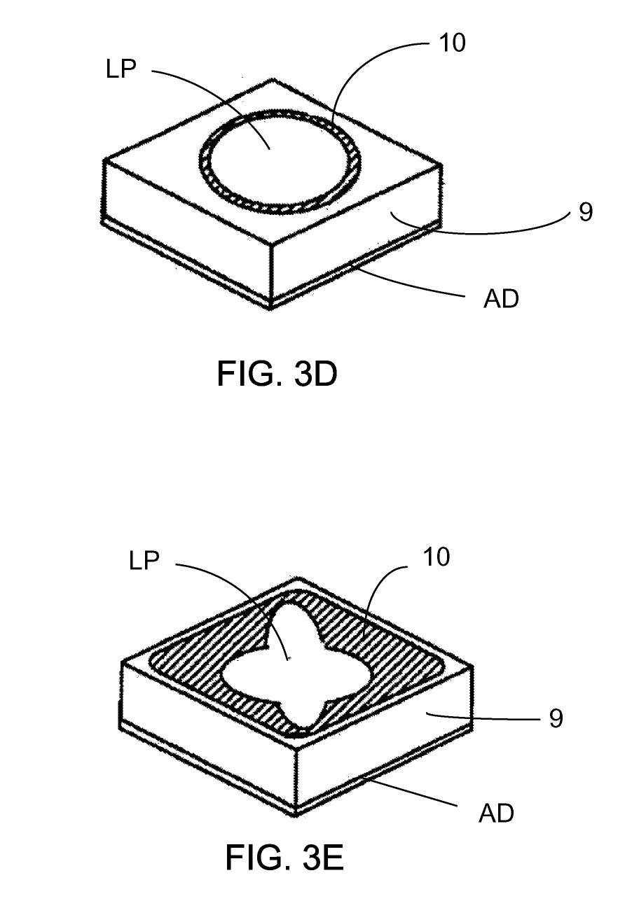

Now, a MAP method employing the supporting board shown in FIG. 1 will be explained with reference to FIG. 3 and subsequent figures.

Initially, our explanation will be directed to an optically-transparent element 9. As shown in FIG. 3A, a large glass plate 20 is prepared. On the top surface side of this glass plate 20, protection films 10 are formed in a matrix manner as shown in this figure. In this illustration, for the convenience purposes, the number of protection films 10 is sixteen. However, the actual size of each of the protection film 10 is about 1.10 mm×1.10 mm, and therefore the actual number will be quite large. On the entire surface, an antireflection coating, such as, e.g., a TiN coating, is formed. The antireflection coating is covered by photo solder resist. After patterning the photo solder resist, the antireflection coating is patterned via the patterned photo solder resist. Each protection film 10 is formed into a rectangular shape as seen from the above and has a round through-hole corresponding to the light passing region LP. This light passing region LP is round in shape. If light is irradiated obliquely, the shape of the through-hole will become an oval shape. If two lights are irradiated obliquely in an overlapped manner, the shape will be a cross-shape. Thus, the through-hole shape can be set variously, such as, e.g., a round shape, an oval shape, a so-called Ninja-star shape in which two oval shapes are overlapped (see FIGS. 3C and 3E). Furthermore, as explained previously, in cases where imide series resins are employed, it is preferable to subject the entire large glass plate 20 to a heat treatment and a polymerization treatment.

The dotted lines shown in FIG. 3A denote virtual dividing lines DL along which the dicing is to be performed. By the dicing, as shown in FIG. 3B, a dice-shaped optically-transparent element 9 is obtained. In this optically-transparent element 9, since the peripheral edge of the protection film 10 retreated inward with respect to the peripheral edge of the glass plate, as shown in FIG. 1C, the insulating resin 11 covers the peripheral edge portion of the top surface of the optically-transparent element 9 up to the protection film 10 to anchor the glass plate. In FIG. 3D, “AD” denotes an adhesive layer. On the other hand, in a modified embodiment shown in FIG. 3D, this protection film 10 can be formed up to the dividing line DL. Dicing can be performed along such dividing lines DL. In this case, in the same manner as in the embodiment shown in FIG. 1A, the side surface of the glass plate 9 and the periphery of the protection film 10 coincide with each other.

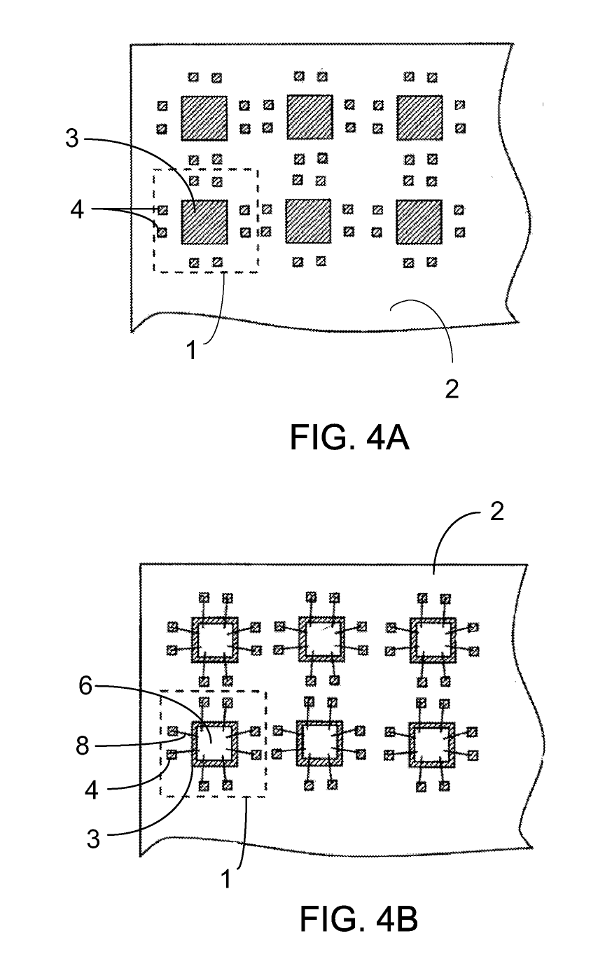

Referring to FIG. 4, FIG. 4A shows a large supporting board 2 on which conductive patterns constituting units are arranged in a matrix manner. Each unit 1 surrounded by a dotted line is constituted by an island 3 and eight inner electrodes 4 arranged around the island 3. Although not shown in FIG. 4A, one unit of outer electrodes is provided on the rear surface of the supporting board 2 in a matrix manner. The island 3 and the connecting portion of the electrode (lead) is coated by Ni and Au in this order from the surface thereof by plating.

Next, as shown in FIG. 4B, a semiconductor chip 6 is attached on each island 3, and the connection electrode 7 of the semiconductor chip 6 and the inner electrode 4 are electrically connected with a metal thin wire 8.

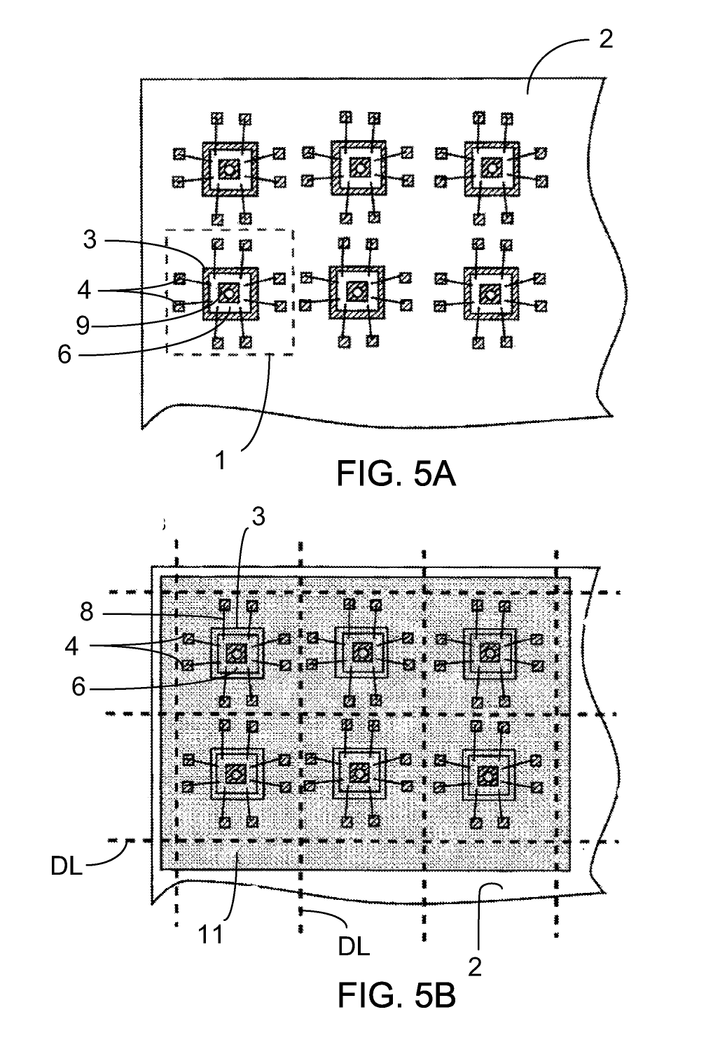

Thereafter, as shown in FIG. 5A, an optically-transparent element 9 is attached on the semiconductor chip 6. This attachment can be performed by applying transparent adhesive agent on the semiconductor chip 6 and then arranging the optically-transparent element 9 thereon. This arrangement can be performed by sucking the optically-transparent element 9 with a suction collet of a mounter and then simply disposing it on the semiconductor chip 6. Alternatively, an adhesive sheet can be arranged on the rear surface of the glass plate (optically-transparent element) 9.

Now, an example using a photodiode as a semiconductor chip will be briefly explained. In general, a diffusion region is formed in a semiconductor substrate at a PN-injunction. When light is irradiated on it, an output is created depending on the strength of the light. When seen in a plan view, four photodiodes are arranged in a matrix arrangement,” the outputs thereof are compared with, for example, a differential circuit to thereby judge whether or not the incoming light is positioned just in the center thereof. In order that the light can reach the diffusion region, the passivation film corresponding to the diffusion region can be removed. In this case, an adhesive agent of the optically-transparent element 9 comes into contact with a passivation film surrounding the removed region.

Next, as shown in FIG. 5B, this supporting board 2 is set to a molding die. In general, the inner surfaces of upper and lower dies constituting a cavity are flat. In other words, in an upper die, the upper surface (inner surface) is formed into a flat shape. In a lower die, the bottom surface (inner surface) is formed into a flat shape. The supporting board 2 is set so that the protection film 10 is in contact with the surface of the molding die. In most cases, it is constituted such that the supporting board 2 is arranged on a lower die and then the lower die is raised so that both the dies clump the periphery of the supporting board 2. The upper surface of the upper die comes into contact with the protection film 10. The units arranged in a matrix manner are disposed in a single cavity and the plurality of units are simultaneously sealed.

The insulating resin 11 injected through a gate contains fillers, such as, e.g., particles of silicon oxide (silica), alumina, or resin balls, to adjust the coefficient of thermal expansion.

In cases where the protection film 10 is in direct contact with the inner surface of the molding die, a slight pressure is applied to the protection film 10. Therefore, the protection film 10 is completely sealed by being pressed from the above. For this reason, depending on the thickness of the protection film 10, in some cases, when removed from the molding die, the protection film 10 is released from the pressure, which causes a slight upward expansion of the protection film 10 from the top surface of the package by several micron order. In order to prevent the insulating resin 11 from being introduced into the portion surrounded by the protection film 10, it can be configured such that a peelable resin sheet is adhered to the entire inner surface of an upper die. In this structure, when the protection films 10 come into contact with the resin sheet, the entire area of the protection films 10 arranged in a matrix manner can be sealed with a high degree of accuracy.

Lastly, the molded article is removed from the molding die and subjected to dicing along the dotted lines DL to obtain semiconductor devices as shown in FIG. 1A.

Next, an example employing a lead frame 30 will be explained.

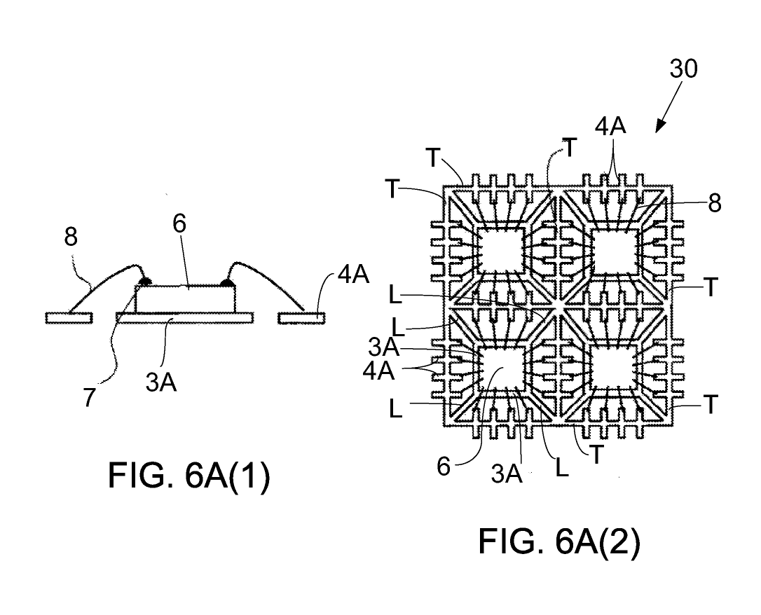

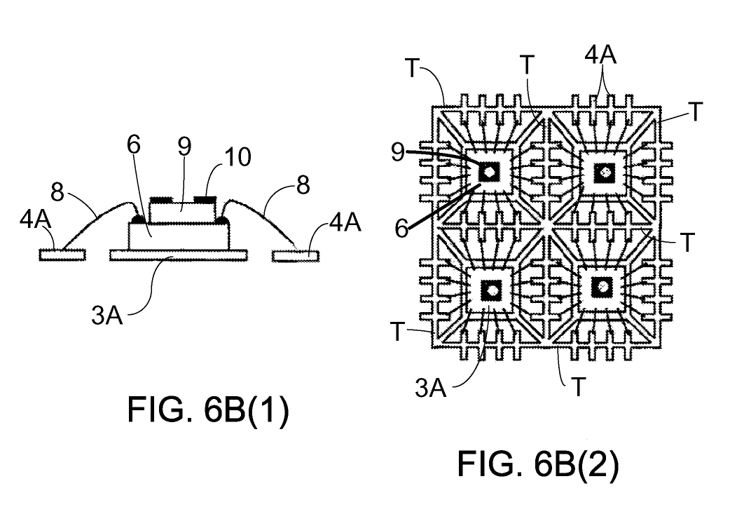

FIG. 6A(2) shows a lead frame 30, and FIG. 6A(1) shows a cross-section of the unit which will constitute a semiconductor device.

As shown in FIG. 6A(2), each unit includes an island 3A. From each of the four corners of the island 3A, a hanging lead L is extended. Along each side of the island 3A, a plurality of leads (electrodes) 4A having one end extending inward and the other end extending outward are arranged. Units each corresponding to a semiconductor device are arranged in a matrix manner, tie bars T extending in a reticular pattern are arranged on the area which correspond to dicing lines. In this arrangement shown in FIG. 6A(2), units are arranged right and left, and the leads 4A of the right side unit and the leads 4A of the left side unit are supported by a single tie bar T. This is also applied to the remaining three tie bars T. Each hanging lead L extends to the intersecting point of the tie bars T or therearound, and is integrated therewith.

In this embodiment, semiconductor chips 6 are mounted on corresponding islands 3A of the lead frame 30, and connection electrodes 7 of each semiconductor chip 6 and the corresponding leads 4A are electrically connected with metal thin wires 8.

After preparing this frame lead 30, the optically-transparent elements 9 produced as shown in FIG. 3 are mounted on the frame lead 30 as shown in FIGS. 6B(1) and 6B(2). The optically-transparent element 9 is sucked with a suction collet provided at a bonder and then disposed on the semiconductor chip 6.

If metal thin wires are bonded after disposing the optically-transparent element 9 on the semiconductor chip 6, there is a possibility that a bonding head comes into contact with the optically-transparent element 9, which is not preferable.

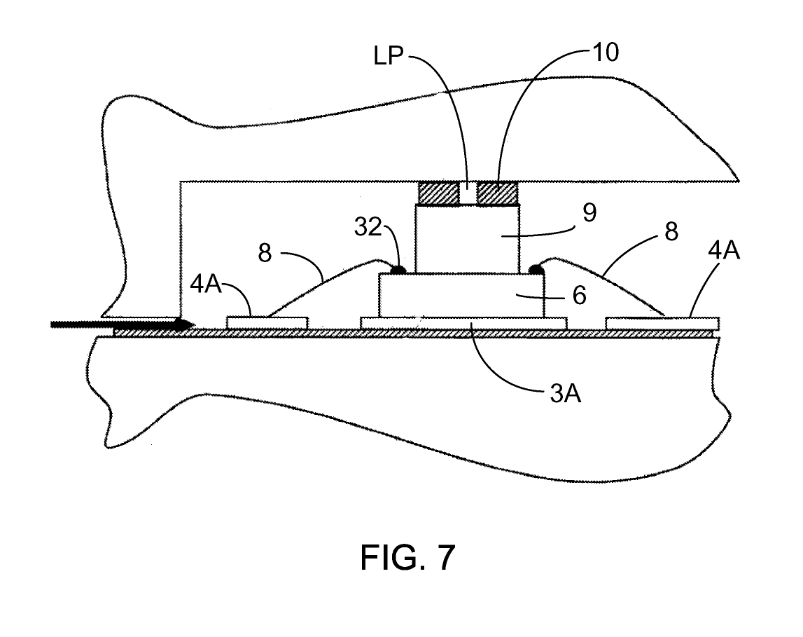

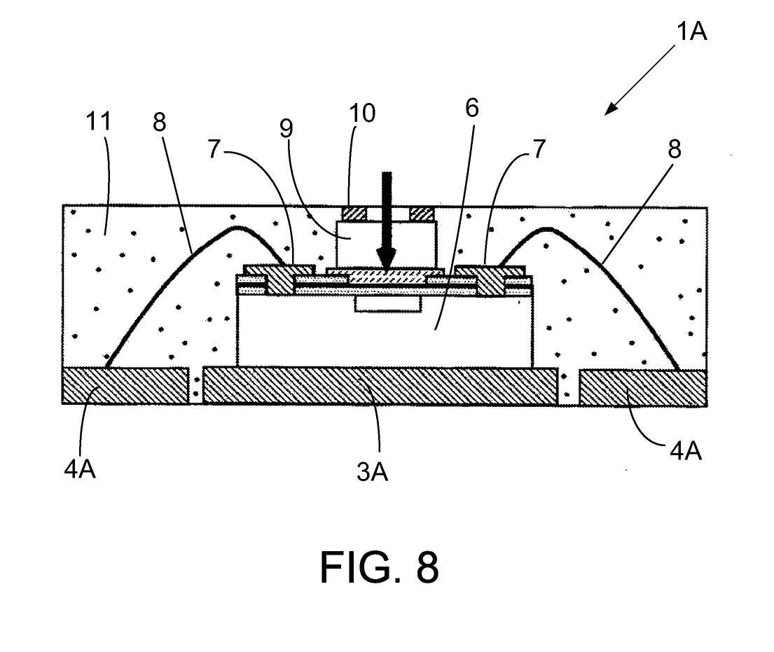

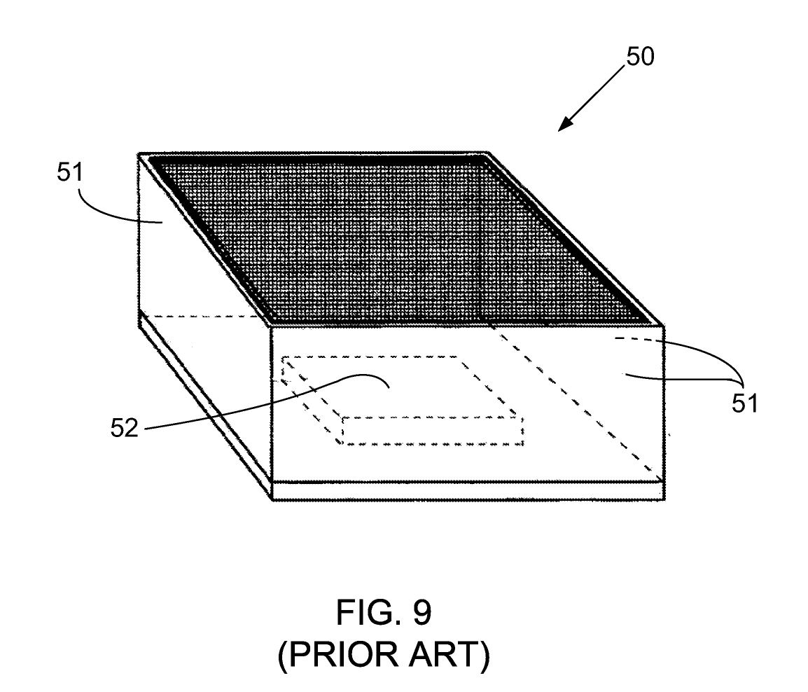

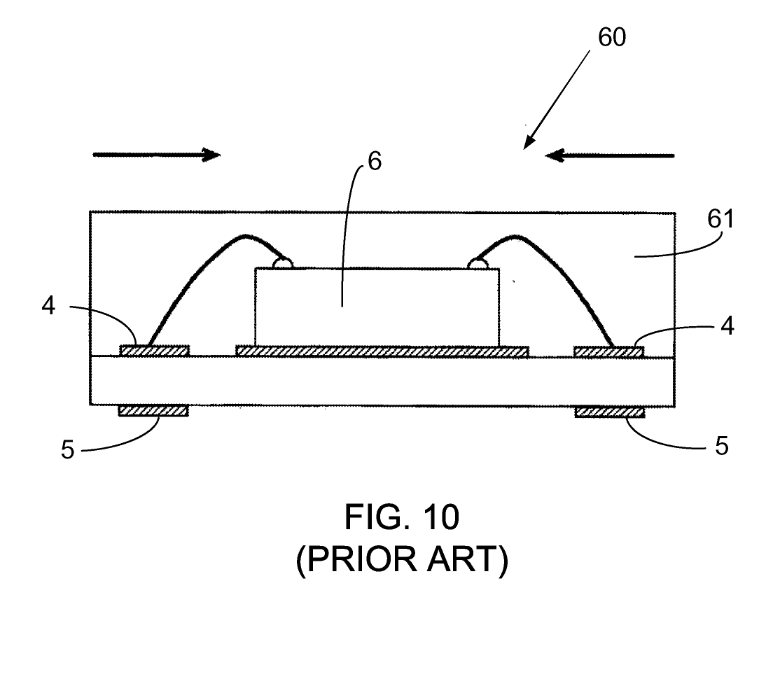

Next, as shown in FIG. 7, the lead frame 30 is mounted on a molding die to perform transfer molding. In this case, since the protection film 10 is brought into contact with the inner surface of the upper die to be molded, the surface of the insulating resin and the surface of the protection film 10 substantially become flush with each other.

Lastly, the molded lead frame 30 is removed from the molding die after the molding, and dicing is performed along the tie bars T to obtain individual chip.

As explained above, in the aforementioned embodiments, the optically-transparent element is made of an optically transparent material, and the protection film is formed to surround the light passing region. Accordingly, the remaining portion of the semiconductor chip can be sealed with a filler-contained insulating resin. This enables adjustment of the coefficient of thermal expansion a of the insulating resin 11. Furthermore, in cases where an arithmetic IC is embedded other than a light receiving/emitting portions, the IC portion can also be sealed with a filler-contained insulating resin 11. Thus, a semiconductor device high in reliability can be provided.

Furthermore, the protection film is arranged on the top surface of the optically-transparent element so as to surround the light passing region, and the protection film is configured to be brought into contact with the inner surface of the molding die during the molding process. This prevents introduction of the insulating resin into the light passing region. Thus, sealing with a filler-contained insulating resin can be performed almost entirely, and therefore the same high reliability as a normal semiconductor package can be secured.

Furthermore, since the sealing is performed in a state in which the surface of the insulating resin is flush with the surface of the protection film, it becomes possible to prevent possible occurrence of damages of the optically-transparent element and/or dust adhesion to the optically-transparent element.

Thus, a package which is capable of being mass-produced by a very simple method can be provided in a reliable state.

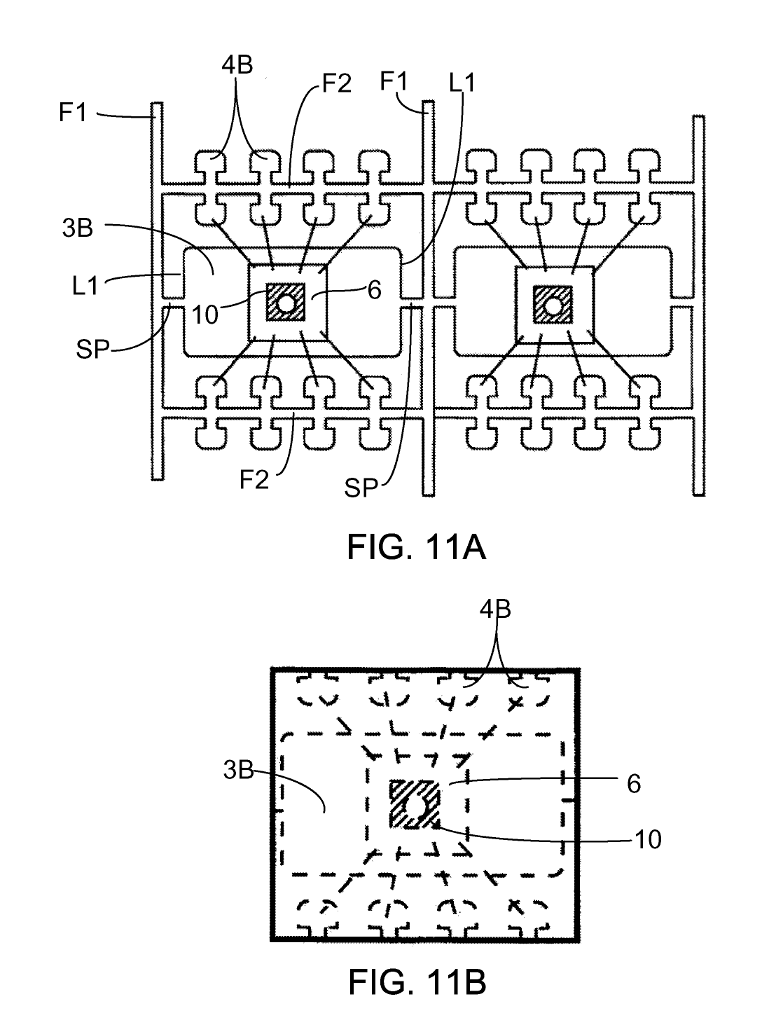

An embodiment shown in FIG. 11 is an alternative of the lead frame shown in FIG. 6. The embodiment shown in FIG. 6 becomes a QFN package, and the embodiment shown in FIG. 11 becomes a VSON package. Supporting leads SP are extended from the opposed sides L1 of the island 3B, and are integrated with the first frame F1. A second frame F2 extending perpendicular to the first frame F1 is provided with leads (electrodes) 4B extending toward the island 3B. This is sealed by a lead frame MAP method, and therefore after the integral molding, dicing is performed along the frames F1 and F2.

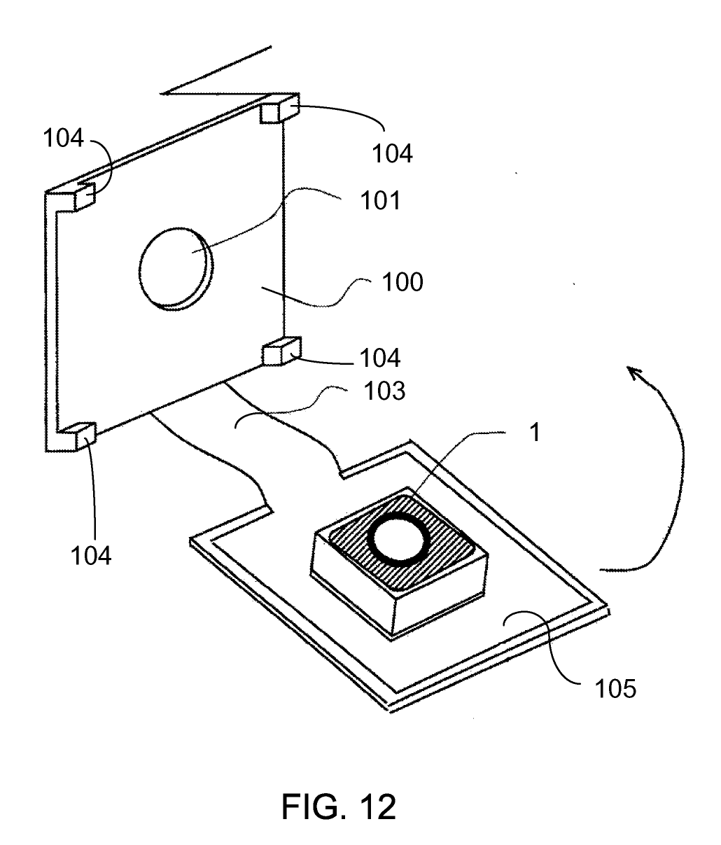

FIG. 12 shows an example in which the semiconductor device according to the present invention is employed as an optical pickup module. The reference numeral “100” denotes a housing for the optical pickup. The housing 100 has an opening 101 for allowing the laser light to reach the semiconductor device 1. Below the housing 100, a printed-circuit board 105 constituting a circuit is provided. The terminals of this printed-circuit board 105 and the circuit of a flexible sheet 103 are connected. A printed-circuit board 105 is integrally formed with the flexible sheet 103, and the semiconductor device 1 is provided on the printed-circuit board 105. By bending the flexible sheet 103, the semiconductor device 1 is arranged inside the fixing portions 104. The printed-circuit board 105 and the fixing portions 104 are fixed with adhesive agent.

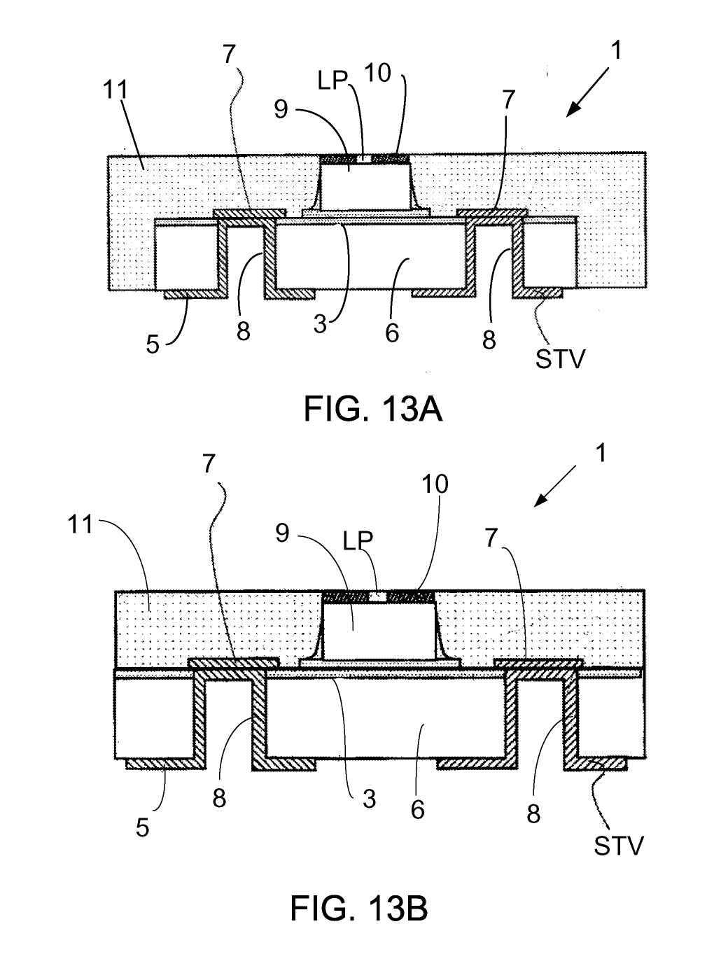

In embodiments shown in FIGS. 13A and 13B, as a semiconductor device and the supporting board, a Si semiconductor substrate is employed. The substrate is provided with a through-hole electrode STV, and the connecting electrode 7 and the outer electrode 5 are electrically connected. A light receiving portion LP is provided inside the Si semiconductor substrate, and an optically-transparent element 9 is provided thereon. In these embodiments, since the semiconductor chip and the supporting board are shared, which enables further reduction of the thickness. In the embodiment shown in FIG. 13A, the insulating resin 11 covers up to the peripheral side of the substrate. In the embodiment shown in FIG. 13B, the side surface of the substrate and the side surface of the resin 11 coincide with each other. The other structures are the same as those of the aforementioned embodiments, and therefore the cumulative explanation will be omitted by allotting the same or corresponding structures as those of the aforementioned embodiments.

It should be noted that a Si interposer can be employed as the supporting board shown in FIG. 1. In this case, the remaining structure can be essentially the same as that shown in FIG. 1 except that a Si substrate is used in place of the supporting board material.

Hereinafter, some preferable embodiments of the present invention will be explained with reference to the attached drawings.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” is meant as a non-specific, general reference and may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

What is claimed is:

1. A semiconductor device comprising:
a semiconductor chip configured to receive or emit light;
a chip mounting region for mounting the semiconductor chip;
an electrode arranged around the chip mounting region;
an electric connecting element which electrically connects the semiconductor chip and the electrode;
an optically-transparent element arranged on a top surface of the semiconductor chip and made of optically-transparent material;
a protection film arranged on a top surface of the optically-transparent element so as to surround a light passing region through which the light passes; and
a filler-contained insulating resin which seals the semiconductor chip, the electric connecting element, the electrode, the optically-transparent element, and the protection film in a state in which a top surface of the protection film and the light passing region surrounded by the protection film are exposed outside.

2. The semiconductor device as recited in claim 1, further comprising a supporting board on which a semiconductor chip mounting island formed in the chip mounting region and the electrode are arranged.

3. The semiconductor device as recited in claim 2, further comprising an outer electrode arranged on a rear surface of the supporting board, wherein the electrode and the outer electrode are electrically connected.

4. The semiconductor device as recited in claim 1, wherein the protection film is arranged in an inner region of the top surface of the optically-transparent element positioned inwardly of an outer peripheral edge of the top surface of the optically-transparent element, and wherein the insulating resin seals an outer peripheral region of the top surface of the optically-transparent element surrounding the inner region of the top surface of the optically-transparent element.

5. The semiconductor device as recited in claim 1, wherein the protection film is made of polymerized resin.

6. The semiconductor device as recited in claim 1, wherein the protection film is made of a material softer than a material of the insulating resin.

7. The semiconductor device as recited in claim 6, wherein the protection film is made of polyimide resin.

8. The semiconductor device as recited in claim 1, wherein the optically-transparent element is an optically-transparent plate.

9. The semiconductor device as recited in claim 1, wherein a top surface of the protection film and a top surface of the insulating resin are substantially flush with each other.

10. The semiconductor device as recited in claim 8, wherein the optically-transparent plate is a glass plate or a resin plate.

11. The semiconductor device as recited in claim 1, wherein the optically-transparent element is rectangular, circular, elliptical, or cross in a plan view.

12. A method of producing a semiconductor device, comprising the steps of:
preparing a plurality of semiconductor units each including a semiconductor chip configured to receive or emit light, a chip mounting region for mounting the semiconductor chip, an electrode arranged around the chip mounting region, an electric connecting element which electrically connects the semiconductor chip and the electrode, an optically-transparent element arranged on a top surface of the semiconductor chip and made of optically-transparent material, and a protection film arranged on a top surface of the optically-transparent element so as to surround a light passing region through which the light passes;
arranging the plurality of semiconductor units in a molding die in a matrix manner;
filling a filler-contained resin in the molding die so that the plurality of semiconductor units are sealed with the filler-contained resin in a state in which a top surface of the protection film and the light passing region surrounded by the protection film of each of the plurality of the semiconductor units are exposed outside;
removing the plurality of semiconductor units from the molding die; and
dicing the plurality of semiconductor units to obtain a plurality of detached semiconductors.

13. The method as recited in claim 12, wherein the plurality of semiconductor units are arranged on a supporting board.

14. The method as recited in claim 12, wherein the optically-transparent element is formed by dicing or punching a secondary unit comprising a glass plate or a transparent resin plate and the protection film formed on the plate by solder resist or polymerization.

15. The method as recited in claim 12, wherein the step of filling the filler-contained resin is performed in such a manner that the protection film is in direct-contact with an inner surface of the molding die or in indirect-contact with the inner surface of the molding die via a resin sheet adhered to the inner surface of the molding die so that the filler-contained resin is prevented from being flowed into the light passing region.
